(19) United States
(12) Patent Application Publication
(10) Pub. No.: US 2025/0022777 A1
(43) Pub. Date: Jan. 16, 2025

(54) SEMICONDUCTOR DEVICE

(71) Applicant: ROHM CO., LTD., Kyoto-shi (JP)

(72) Inventor: Shingo YOSHIDA, Kyoto-shi (JP)

(21) Appl. No.: 18/900,109

(22) Filed: Sep. 27, 2024

Related U.S. Application Data
(63) Continuation of application No. PCT/JP2023/010293, filed on Mar. 16, 2023.

(30) Foreign Application Priority Data
Mar. 31, 2022 (JP) 2022-060621

(51) Int. Cl. H01L 23/495

(52) U.S. Cl. CPC H01L 23/4952; H01L 23/4951; H01L 23/49513; H01L 23/49555

(57) ABSTRACT

A semiconductor device includes a semiconductor element, a first lead, a sealing resin, and a first connecting member. The first lead includes a die pad portion that includes a die-pad obverse surface facing a first side in a thickness direction, and a support portion supporting the die pad portion. The semiconductor element is mounted on the die-pad obverse surface. The sealing resin covers the semiconductor element. The first connecting member is electrically connected to the support portion and electrically conductive to the semiconductor element. The support portion includes a connecting surface to which the first connecting member is electrically connected. The connecting surface and the die-pad obverse surface are different in position in the thickness direction.

### TECHNICAL FIELD

The present disclosure relates to a semiconductor device.

### BACKGROUND ART

Various semiconductor devices have been developed conventionally. For example, JP-A-2020-77665 discloses an example of a semiconductor device. The semiconductor device includes a semiconductor element, a die pad, a plurality of terminals, a plurality of wires, and a sealing resin. The semiconductor element is mounted on the die pad, and a plurality of electrodes are electrically connected to the terminals by the wires. When the electrodes of the semiconductor element are to be electrically conducted to the die pad, the electrical connection between the electrodes and the die pad is established by the wires.

### BRIEF DESCRIPTION OF THE DRAWINGS

FIG. 1 is a perspective view showing a semiconductor device according to a first embodiment of the present disclosure.

FIG. 2 is a plan view showing the semiconductor device of FIG. 1, as seen through a sealing resin.

FIG. 3 is a bottom view showing the semiconductor device of FIG. 1.

FIG. 4 is a front view showing the semiconductor device of FIG. 1.

FIG. 5 is a right-side view showing the semiconductor device of FIG. 1.

FIG. 6 is a cross-sectional view along line VI-VI in FIG. 2.

FIG. 7 is a cross-sectional view along line VII-VII in

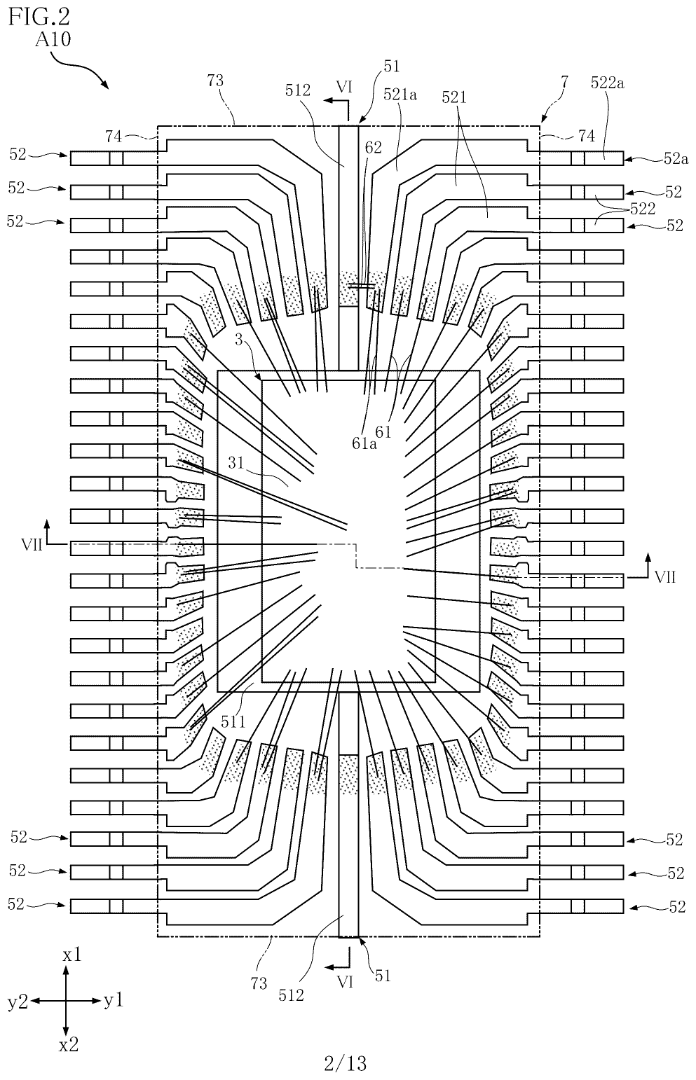

FIG. 2.

FIG. 8 is a partially enlarged view showing a part of FIG. 2.

FIG. 9 is a partially enlarged plan view showing a semiconductor device according to a first variation of the first embodiment.

FIG. 10 is a partially enlarged plan view showing a semiconductor device according to a second variation of the first embodiment.

FIG. 11 is a partially enlarged plan view showing a semiconductor device according to a second embodiment of the present disclosure.

FIG. 12 is a partially enlarged plan view showing a semiconductor device according to a third embodiment of the present disclosure.

FIG. 13 is a plan view showing a semiconductor device according to a fourth embodiment of the present disclosure, as seen through a sealing resin.

### DETAILED DESCRIPTION OF EMBODIMENTS

The following describes preferred embodiments of the present disclosure in detail with reference to the drawings. In the following description, identical or similar elements are provided with the same reference numerals, and descriptions thereof are omitted. The terms such as “first”, “second” and “third” in the present disclosure are used merely as labels and not intended to impose orders on the elements accompanied with these terms.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Further, the phrase “an object A overlaps with an object B as viewed in a certain direction” includes, unless otherwise specified, “an object A overlaps with the entirety of an object B” and “an object A overlaps with a portion of an object B”. Further, the phrase “an object A (or the material thereof) contains a material C” includes “an object A (or the material thereof) is made of a material C” and “an object A (or the material thereof) is mainly composed of a material C”.

### First Embodiment

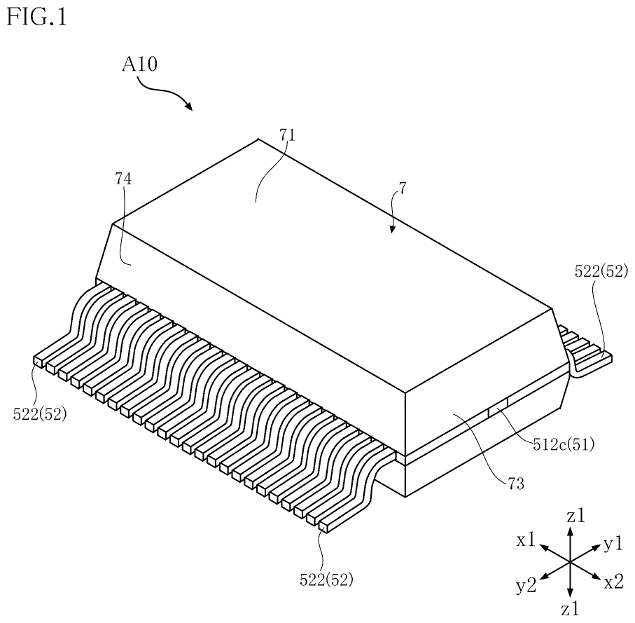

FIGS. 1 to 8 show a semiconductor device A10 according to a first embodiment. For convenience of understanding, FIG. 2 shows a sealing resin 7 in phantom, and the outer shape of the sealing resin 7 is indicated by an imaginary line (two-dot chain line). In the present embodiment, the semiconductor device A10 is provided in a small outline package (SOP). Note that the package type, application, and function of the semiconductor device A10 are not particularly limited. The semiconductor device A10 can be used in electronic devices, general industrial devices, and vehicle-mounted devices, for example. The shape and size of the semiconductor device A10 are not particularly limited.

For convenience of description, the thickness direction of the semiconductor device A10 is defined as a z direction, and a direction along one side of the semiconductor device A10 that is perpendicular to the z direction is defined as an x direction (the vertical direction in FIG. 2). The direction perpendicular to the z direction and the x direction is defined as a y direction (the horizontal direction in FIG. 2). The x direction is an example of a “first direction”, and the y direction is an example of a “second direction”.

The semiconductor device A10 includes a semiconductor element 3, a lead 51, a plurality of leads 52, a plurality of wires 61, a plurality of wires 62, and a sealing resin 7.

The semiconductor element 3 is an element that exerts an electrical function of the semiconductor device A10. The type of the semiconductor element 3 is not particularly limited. In the present embodiment, the semiconductor element 3 is an LSI (Large-Scale Integration). In the present embodiment, the semiconductor element 3 has a rectangular shape as viewed in the z direction (in plan view).

The semiconductor element 3 includes an element obverse surface 31, an element reverse surface 32, and a plurality of electrode pads 33. The element obverse surface 31 and the element reverse surface 32 face away from each other in the z direction. The element obverse surface 31 faces a z1 side in the z direction. The element reverse surface 32 faces a z2 side in the z direction. As shown in FIG. 8, the electrode pads 33 are disposed on the element obverse surface 31. Note that FIG. 2 omits the electrode pads 33. Further, the number and arrangement of the electrode pads 33 are not particularly limited. The electrode pads 33 include an electrode pad 33a. In the present embodiment, the number of electrode pads 33a is two, and the electrode pads 33a are ground electrode pads. The electrode pads 33a are not limited to those for grounding, and may be of different types. The number of electrode pads 33a is not particularly limited. The semiconductor element 3 is mounted on the lead 51.

The lead 51 and the leads 52 (hereinafter, also collectively referred to as a “conductive support member 5) support the semiconductor element 3 and serve as terminals used to mount the semiconductor device A10 onto a wiring board. The conductive support member 5 is made of a lead frame formed by etching or stamping a metal plate, for example. The conductive support member 5 contains a metal selected from Cu, Ni, iron (Fe), etc., and an alloy of Cu, Ni, iron (Fe), etc., for example.

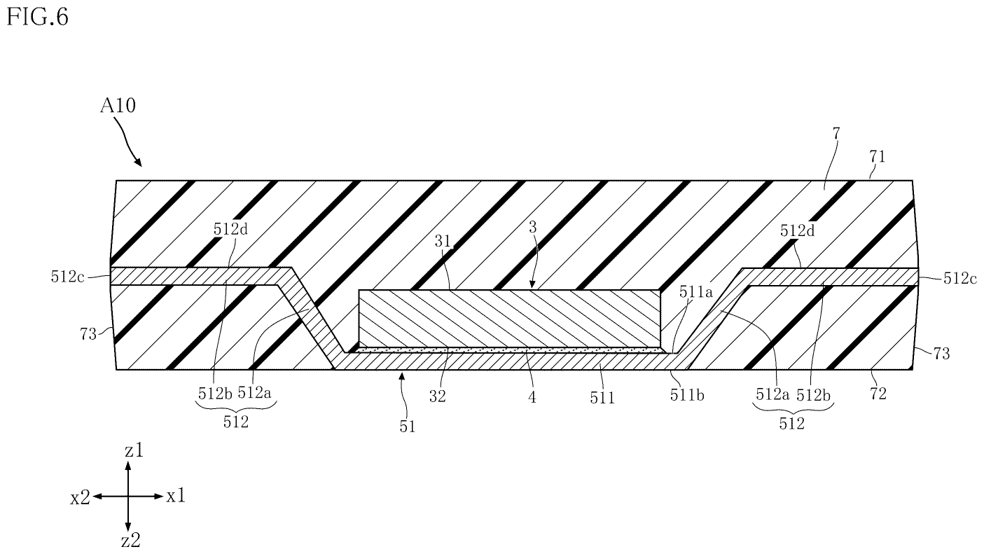

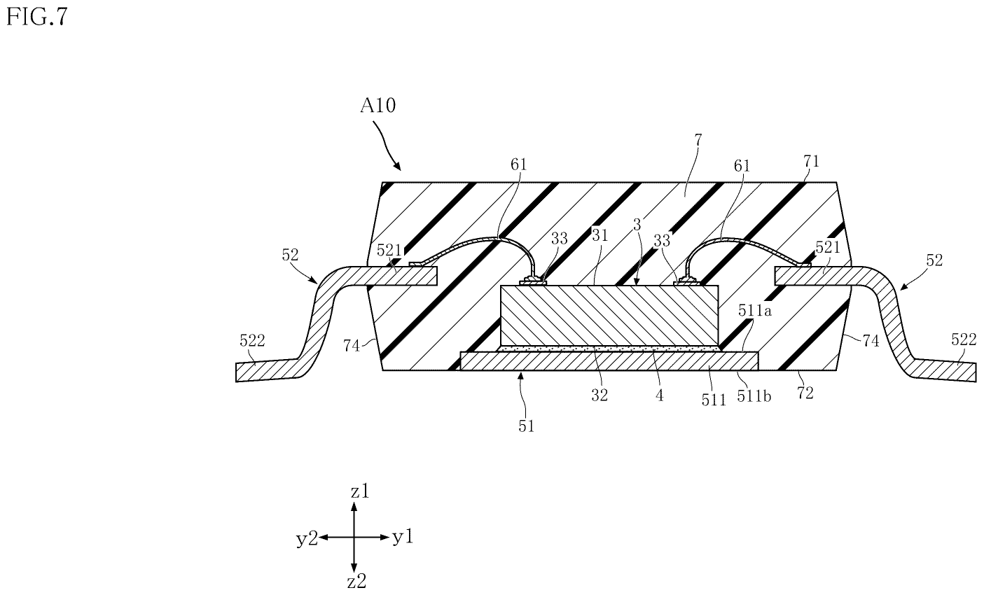

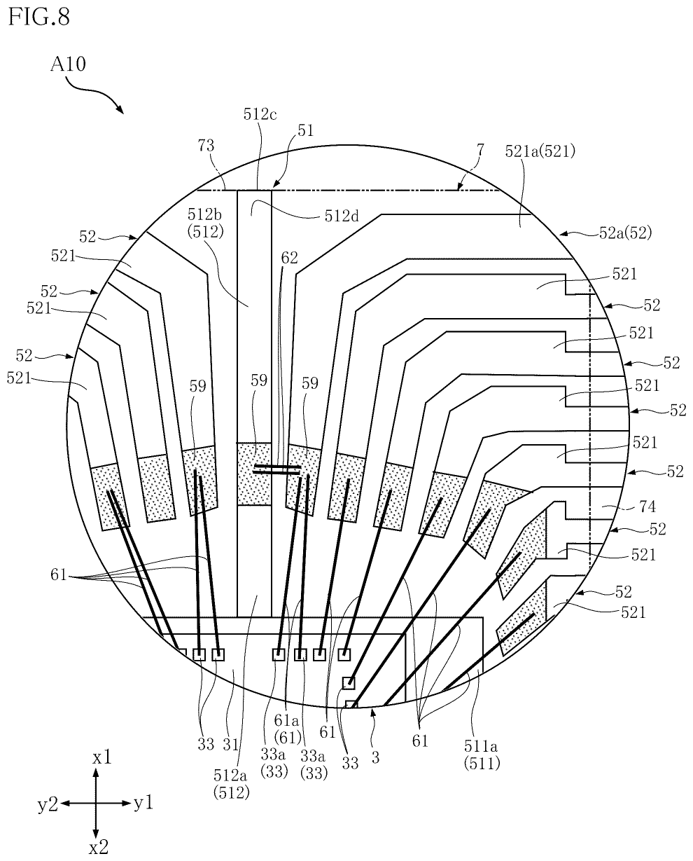

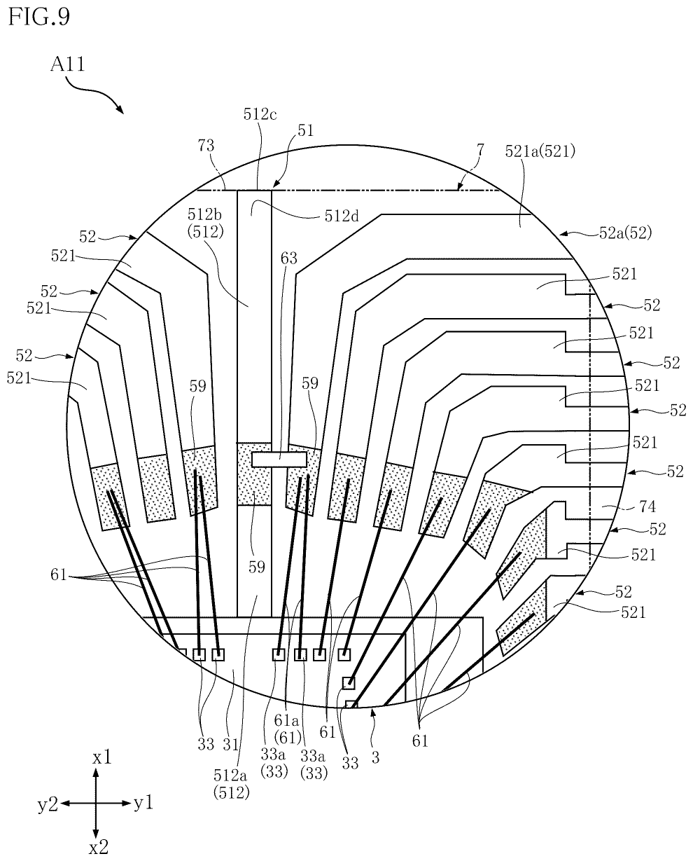

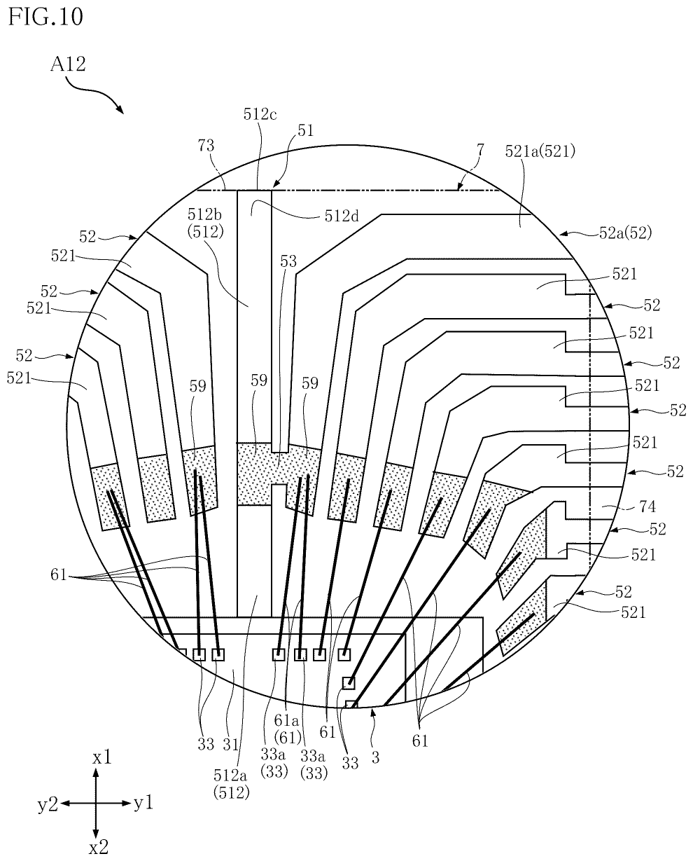

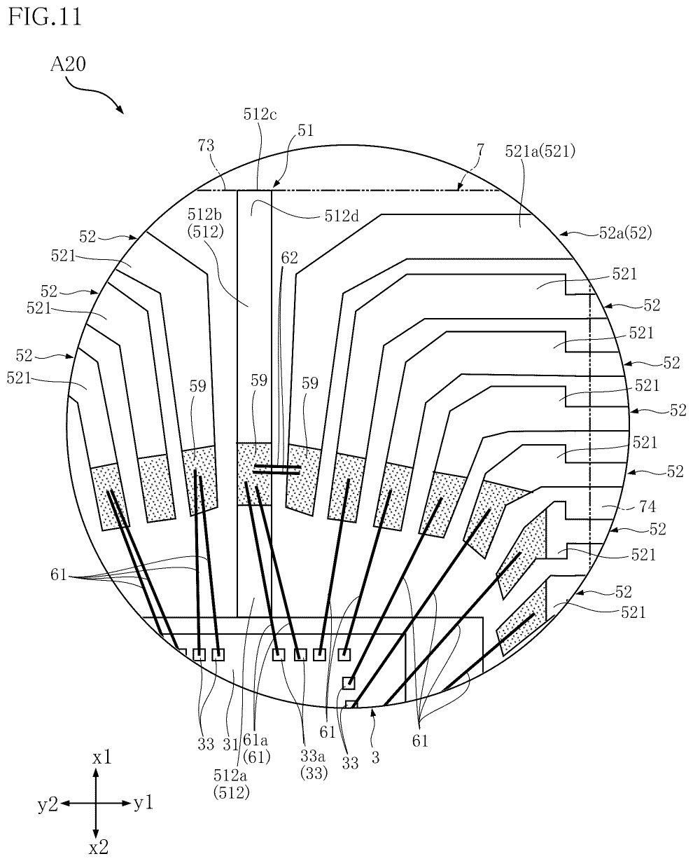

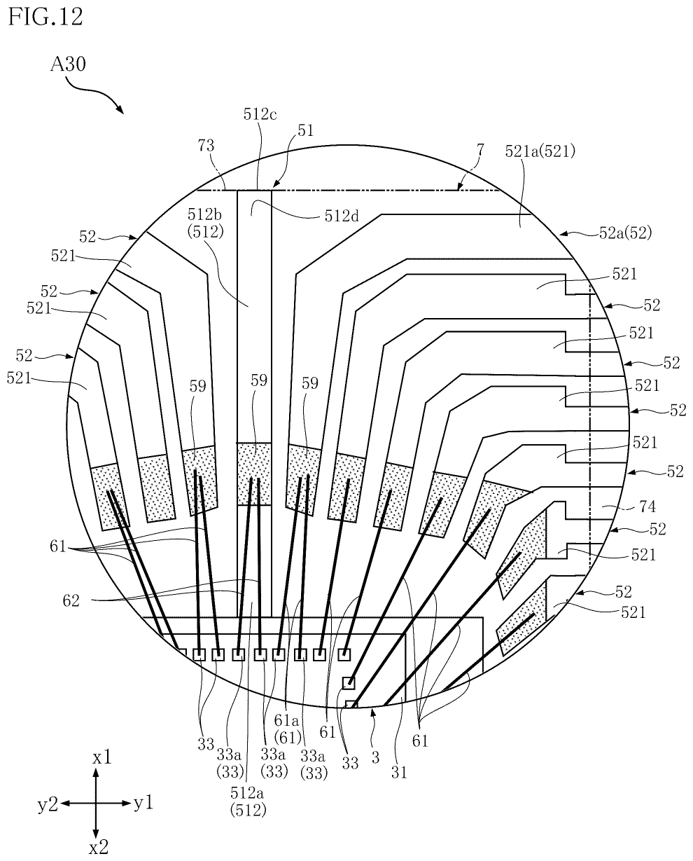

The lead 51 supports the semiconductor element 3. As shown in FIGS. 2 and 6, the lead 51 includes a die pad portion 511 and two support portions 512.

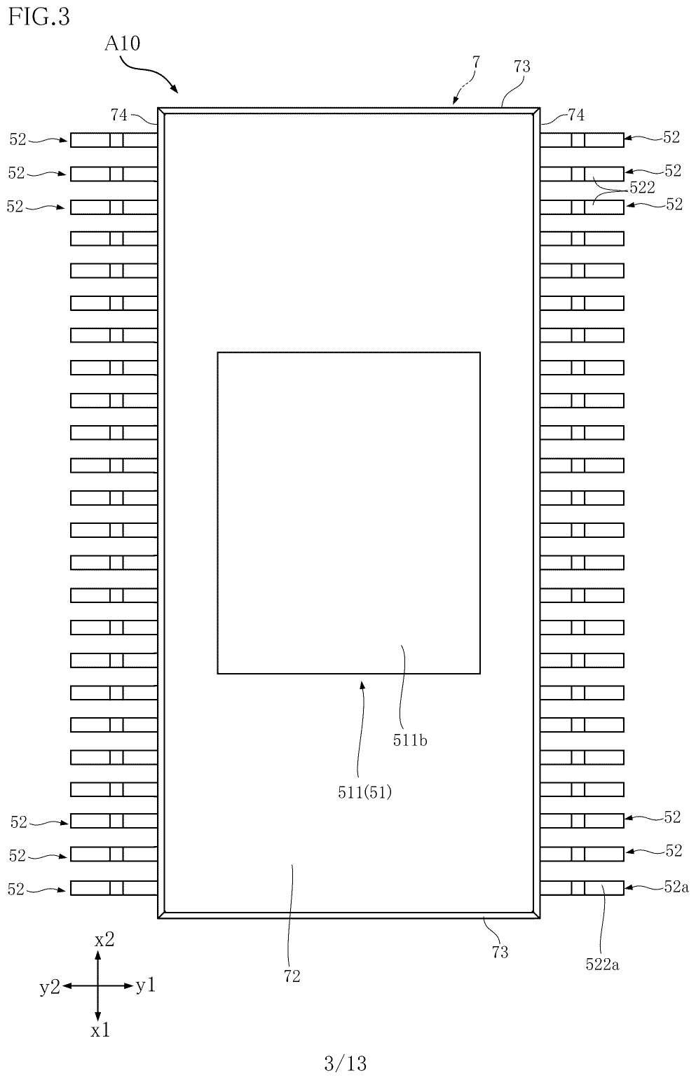

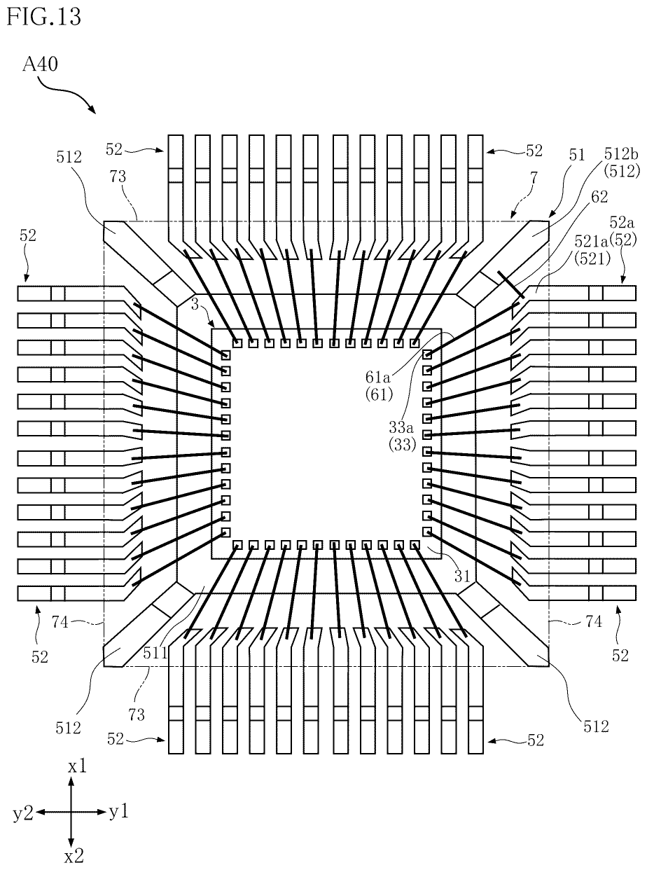

The die pad portion 511 is the portion on which the semiconductor element 3 is mounted. The shape of the die pad portion 511 is not particularly limited. In the example shown in FIG. 2, the die pad portion 511 has a rectangular shape in plan view. As shown in FIGS. 6 and 7, the die pad portion 511 has a die-pad obverse surface 511a and a die-pad reverse surface 511b. The die-pad obverse surface 511a faces the z1 side in the z direction. The die-pad reverse surface 511b faces the opposite side from the die-pad obverse surface 511a in the z direction (the z2 side in the z direction). In the illustrated example, the die-pad obverse surface 511a and the die-pad reverse surface 511b are flat surfaces. The semiconductor element 3 is bonded to the die-pad obverse surface 511a via a bonding member 4. Specifically, the element reverse surface 32 of the semiconductor element 3 is bonded to the die-pad obverse surface 511a via the bonding member 4. In the present embodiment, the bonding member 4 is made of an insulating bonding material having high thermal conductivity in order to insulate the element reverse surface 32 and the die pad portion 511 from each other and to dissipate heat generated by the semiconductor element 3 to the die pad portion 511. It suffices for the bonding member 4 to have thermal conductivity, and the bonding member 4 may be an electroconductive bonding member. As shown in FIGS. 3, 6, and 7, the die-pad reverse surface 511b is exposed from the sealing resin 7 (a resin reverse surface 72 described below).

As viewed in the z direction, the semiconductor element 3 occupies a large area of the die pad portion 511. An area S1 of the element obverse surface 31 of the semiconductor element 3 is 50% to 90% of an area S2 of the die-pad obverse surface 511a of the die pad portion 511. It is difficult to connect a bonding wire to the die-pad obverse surface 511a because the area of the die-pad obverse surface 511a where the semiconductor element 3 is not disposed is narrow, and the wires 61 that electrically connect the semiconductor element 3 and the leads 52 are densely arranged.

The two support portions 512 are so-called island supports that support the die pad portion 511. As shown in FIGS. 2 and 6, the two support portions 512 are disposed at the respective sides of the die pad portion 511 in the x direction. The support portion 512 disposed at an x1 side in the x direction is connected to the side of the die pad portion 511 facing the x1 side in the x direction at the middle thereof in the y direction. The support portion 512 disposed at an x2 side in the x direction is connected to the side of the die pad portion 512 facing the x2 side in the x direction at the middle thereof in the y direction.

As shown in FIGS. 6 and 8, each of the support portions 512 includes a first portion 512a and a second portion 512b. The first portion 512a is connected to the die pad portion 511 and inclined to the die-pad obverse surface 511a. The first portion 512a is more offset toward the z1 side in the z direction with increasing distance from the die pad portion 511. The second portion 512b is connected to the outer side of the first portion 512a in the x direction and parallel (or substantially parallel) to the die-pad obverse surface 511a. The second portion 512b is at the same position as the leads 52 in the z direction. The second portion 512b includes an exposed surface 512c. The exposed surface 512c is the surface of the second portion 512b that faces in the x direction, and is exposed from the sealing resin 7. The exposed surface 512c is a cut surface created when the lead frame is cut. The second portion 512b also includes a connecting surface 512d. The connecting surface 512d is the surface of the second portion 512b that faces the z1 side in the z direction and to which the wires 61 and/or 62 are connected. As shown in FIG. 6, the connecting surface 512d is offset from the die-pad obverse surface 511a to the z1 side in the z direction. In the present embodiment, the portion of the connecting surface 512d to which the wires 61 and/or 62 are connected is formed with a metal layer 59. In FIG. 2, the portion of the connecting surface 512d where the metal layer 59 is formed is dotted. The metal layer 59 is a plating layer containing Ag, for example, to improve the bondability of the wires 61 and/or 62. Note that the material and arrangement area of the metal layer 59 is not particularly limited, and the metal layer 59 may not be formed on the connecting surface 512d.

As shown in FIG. 2, the leads 52 are spaced apart from the lead 51 and from each other. The leads 52 are disposed around the lead 51 as viewed in the z direction. In the illustrated example, the leads 52 include those disposed on a y1 side in the y direction with respect to the lead 51, and those disposed on a y2 side in the y direction with respect to the first lead 51. As shown in FIGS. 2 and 7, each of the leads 52 includes a pad portion 521 and a terminal portion 522.

The pad portions 521 surround the die pad portion 511 as viewed in the z direction. The shape of each pad portion 521 as viewed in the z direction is not particularly limited. Each of the wires 61 is connected to one of the pad portions 521. Note that some of the pad portions 521 have no wires 61 connected thereto. As shown in FIG. 7, each of the pad portions 521 is offset from the die pad portion 511 to the side (the z1 side in the z direction) that the die-pad obverse surface 511a faces. The portion of each of the pad portions 521 to which a wire 61 is connected is formed with a metal layer 59. In FIG. 2, the portion of each of the pad portions 521 where a metal layer 59 is formed is dotted. Note that the material and arrangement area of the metal layer 59 is not particularly limited, and the metal layer 59 may not be formed on any of the pad portions 521.

The terminal portion 522 extends outward from the pad portion 521 in the y direction. Each of the terminal portions 522 has a strip shape as viewed in the z direction. As shown in FIGS. 2, 3, and 5, the terminal portions 522 of the leads 52 disposed on the y1 side in the y direction with respect to the lead 51 protrude from the sealing resin 7 to the y1 side in the y direction, and are arranged at equal intervals in the x direction. As shown in FIGS. 2 and 3, the terminal portions 522 of the leads 52 disposed on the y2 side in the y direction with respect to the lead 51 protrude from the sealing resin 7 to the y2 side in the y direction, and are arranged at equal intervals in the x direction. As shown in FIG. 7, each terminal portion 522 is bent into a gull-wing shape as viewed in the x direction. As shown in FIG. 7, each terminal portion 522 has a tip (a distal end far from the die pad portion 511 in the y direction) located at the same (or substantially the same) position as the die pad portion 511 in the z direction. The terminal portions 522 of the leads 52 are used as external terminals of the semiconductor device A10.

The leads 52 include a lead 52a. The lead 52a is one of the leads 52 disposed on the y1 side in the y direction with respect to the lead 51, and is closest to the x1 side in the x direction. Hereinafter, the pad portion 521 and the terminal portion 522 of the lead 52a are referred to as a “pad portion 521a” and a “terminal portion 522a”, respectively. The lead 52a is electrically conductive to the electrode pads 33a. Since the electrode pads 33a are ground electrode pads in the present embodiment, the terminal portion 522a functions as a ground terminal.

The wires 61 and the wires 62 (hereinafter, also collectively referred to as “wires 6”) are bonding wires, each of which electrically connects two elements that are spaced apart from each other. The wires 6 contain Cu, for example. The material of the wires 6 is not particularly limited, and may contain Al or Au, for example.

Each of the wires 61 electrically connects one of the electrode pads 33 formed on the element obverse surface 31 of the semiconductor element 3 and the pad portion 521 of one of the leads 52. Each of the wires 61 is bonded to an electrode pad 33 of the semiconductor element 3 and the metal layer 59 formed on the pad portion 521 of a lead 52.

The wires 61 include a wire 61a. In the present embodiment, the number of wires 61a is two. The number of wires 61a is not particularly limited. As shown in FIG. 8, the wires 61a are bonded to the respective electrode pads 33a and the metal layer 59 formed on the pad portion 521a. As a result, the lead 52a is electrically conductive to the electrode pads 33a.

Each of the wires 62 electrically connects the support portion 512 on the x1 side in the x direction and the lead 52a. Each of the wires 62 is bonded to the metal layer 59 formed on the second portion 512b of the support portion 512 on the x1 side in the x direction, and to the metal layer 59 formed on the pad portion 521a of the lead 52a. Although the two wires 62 are provided in the present embodiment, the number of wires 62 is not particularly limited. For example, it is possible to provide a single wire 62 or more than two wires 62. Since the support portion 512 on the x1 side in the x direction is electrically conductive to the electrode pads 33a of the semiconductor element 3 via the wires 62, the pad portion 521a of the lead 52a, and the wires 61a, the die pad portion 511 is electrically conductive to the electrode pads 33a.

The sealing resin 7 covers a portion of each of the first lead 51 and the second leads 52, the semiconductor element 3, the wires 61, and the wires 62. The sealing resin 7 is an insulating resin, and may contain an epoxy resin mixed with a filler. The material of the sealing resin 7 is not particularly limited. The sealing resin 7 includes a resin obverse surface 71, a resin reverse surface 72, two resin side surfaces 73, and two resin side surfaces 74.

The resin obverse surface 71 faces the same side as the die-pad obverse surface 511a in the z direction (the z1 side in the z direction). The resin obverse surface 71 is a flat surface, for example. The resin reverse surface 72 faces the opposite side from the resin obverse surface 71 in the z direction (the same side as the die-pad reverse surface 511b (the z2 side in the z direction)). The resin reverse surface 72 is a flat surface, for example. The die-pad reverse surface 511b is exposed from the resin reverse surface 72. The resin reverse surface 72 and the die-pad reverse surface 511b are flush with each other.

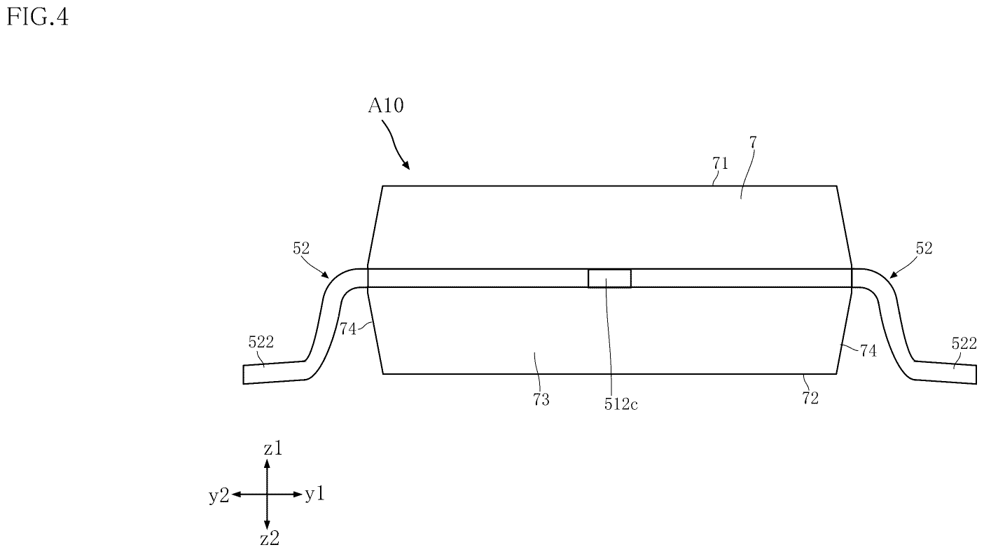

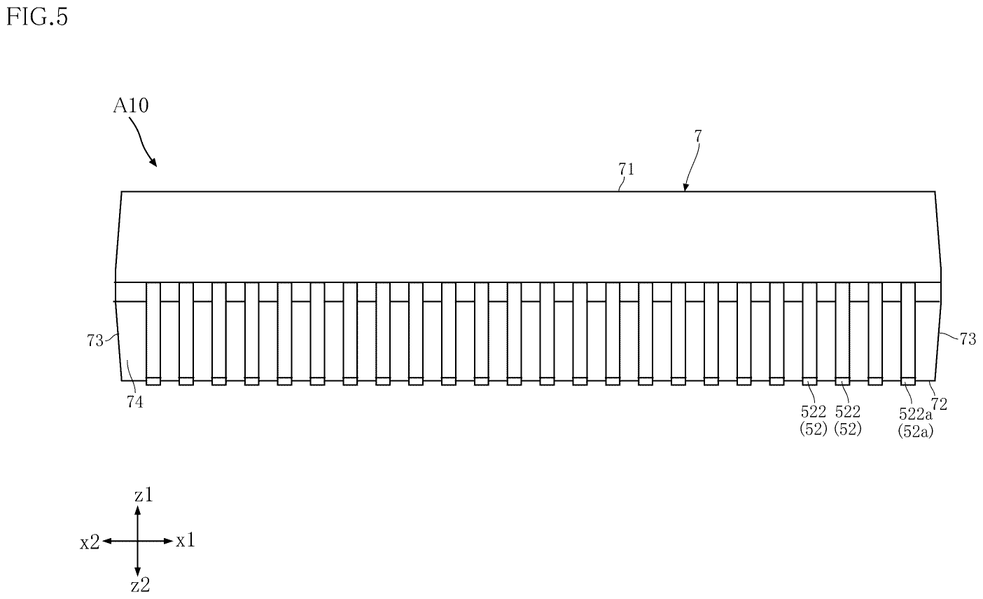

The two resin side surfaces 73 are located between the resin obverse surface 71 and the resin reverse surface 72 in the z direction. As shown in FIG. 5, the resin side surfaces 73 are spaced apart from each other in the x direction and face in the x direction. The exposed surface 512c of each support portion 512 is exposed from one of the resin side surfaces 73. The two resin side surfaces 74 are located between the resin obverse surface 71 and the resin reverse surface 72 in the z direction. As shown in FIG. 4, the resin side surfaces 74 are spaced apart from each other in the y direction and face in the y direction. The terminal portion 522 of each lead 52 protrudes from one of the resin side surfaces 74.

The following describes advantages of the semiconductor device A10.

According to the present embodiment, the support portion 512 on the x1 side in the x direction is electrically conductive to the electrode pads 33a via the wires 62, the pad portion 521a of the lead 52a, and the wires 61a, whereby the die pad portion 511 is electrically conductive to the electrode pads 33a. In other words, the die pad portion 511 is electrically conductive to the electrode pads 33a via the support portion 512 on the x1 side in the x direction, the wires 62, the pad portion 521a, and the wires 61a, instead of being directly and electrically connected to the electrode pads 33a via bonding wires. This allows the semiconductor device A10 to make the semiconductor element 3 and the die pad portion 511 electrically conductive to each other even when the die pad portion 511 does not have enough space for bonding a bonding wire.

According to the present embodiment, the wires 62 are connected to the second portion 512b of the support portion 512 on the x1 side in the x direction and the pad portion 521a of the lead 52a. The second portion 512b and the pad portion 521a are close to each other and located at the same position in the z direction. Thus, it is easy to form the wires 62. In addition, the wires 62 are less likely to contact with the wires 61.

In the case where the wires 62 are connected to the support portion 512 on the x1 side in the x direction and the electrode pads 33a in order to make the semiconductor element 3 and the die pad portion 511 electrically conductive to each other, the semiconductor element 3 needs to be provided with additional electrode pads 33a for the bonding wires 62. According to the present embodiment, the wires 62 are connected to the pad portion 521a, thus eliminating the need for providing the semiconductor element 3 with additional electrode pads 33a.

According to the present embodiment, the number of wires 62 is more than one. Thus, as compared to the case where a single wire 62 is provided, it is possible to pass a larger current between the pad portion 521a and the support portion 512 on the x1 side in the x direction. Further, according to the present embodiment, the number of wires 61a is more than one. Thus, as compared to the case where a single wire 61a is provided, it is possible to pass a larger current between the pad portions 33a and the pad portion 521a.

FIGS. 9 and 10 show a variation of the semiconductor device A10 according to the first embodiment. In these figures, elements that are the same as or similar to those in the above embodiment are provided with the same reference numerals as in the above embodiment, and descriptions thereof are omitted.

### First Variation:

FIG. 9 is a view for explaining a semiconductor device A11 according to a first variation of the first embodiment. FIG. 9 is a partially enlarged plan view showing the semiconductor device A11, and corresponds to FIG. 8. The semiconductor device A11 according to the first variation includes a clip 63 as a connecting member instead of the wires 62. The clip 63 is a plate-like metal member, and may contain a metal selected from Cu, Ni, iron (Fe), etc., and an alloy of Cu, Ni, iron (Fe), etc., for example. The clip 63 is bonded to the metal layer 59 formed on the second portion 512b of the support portion 512 on the x1 side in the x direction, and to the metal layer 59 formed on the pad portion 521a of the lead 52a. In the present variation, the support portion 512 on the x1 side in the x direction and the pad portion 521a are also electrically connected to each other. As can be understood from the first variation, the connecting member for electrically connecting the support portion 512 and the pad portion 521a is not particularly limited.

### Second Variation:

FIG. 10 is a view for explaining a semiconductor device A12 according to a second variation of the first embodiment. FIG. 10 is a partially enlarged plan view showing the semiconductor device A12, and corresponds to FIG. 8. The semiconductor device A12 according to the second variation uses a connecting portion 53 instead of the wires 62 to electrically connect the support portion 512 on the x1 side in the x direction and the pad portion 521a. In the present variation, the conductive support member 5 includes the connecting portion 53. The connecting portion 53 is a plate-like portion integrally connected to the second portion 512b of the support portion 512 on the X1 side in the x direction and the pad portion 521a of the lead 52a. The connecting portion 53 is a part of the lead frame formed by performing a process on a metal plate, and is integrally connected to the second portion 512b and the pad portion 521a. Thus, the surface of the connecting portion 53 facing the z1 side in the z direction is flush with the connecting surface 512d of the support portion 512 on the x1 side in the x direction and the surface of the pad portion 521a that faces the z1 side in the z direction. As can be understood from the second variation, the method for electrically connecting the support portion 512 and the pad portion 521a is not particularly limited.

FIGS. 11 to 13 show other embodiments of the present disclosure. In these figures, elements that are the same as or similar to those in the above embodiment are provided with the same reference numerals as in the above embodiment.

### Second Embodiment

FIG. 11 is a view for explaining a semiconductor device A20 according to a second embodiment of the present disclosure. FIG. 11 is a partially enlarged plan view showing the semiconductor device A20, and corresponds to FIG. 8. The semiconductor device A20 according to the present embodiment is different from the first embodiment in that the wires 61a are electrically connected to the support portion 512 on the x1 side in the x direction. The configurations and operations of other parts of the present embodiment are the same as those of the first embodiment. The present embodiment may be combined with any part of the first embodiment and the variations.

The wires 61a according to the present embodiment are bonded to the respective electrode pads 33a and the metal layer 59 formed on the second portion 512b of the support portion 512 on the x1 side in the x direction.

According to the present embodiment, the support portion 512 on the x1 side in the x direction is electrically conductive to the electrode pads 33a via the wires 61a, whereby the die pad portion 511 is electrically conductive to the electrode pads 33a. In other words, the die pad portion 511 is electrically conductive to the electrode pads 33a via the support portion 512 on the x1 side in the x direction and the wires 61a, instead of being directly and electrically connected to the electrode pads 33a via bonding wires. This allows the semiconductor device A20 to make the semiconductor element 3 and the die pad portion 511 electrically conductive to each other even when the die pad portion 511 does not have enough space for bonding a bonding wire. In addition, since the wires 62 electrically connect the support portion 512 on the x1 side in the x direction and the pad portion 521a, the lead 52a is electrically conductive to the electrode pads 33a. The present embodiment also eliminates the need for providing the semiconductor element 3 with additional electrode pads 33a. Further, the semiconductor device A20 has advantages common to the semiconductor device A10 owing to its common configuration with the semiconductor device A10.

### Third Embodiment

FIG. 12 is a view for explaining a semiconductor device A30 according to a third embodiment of the present disclosure. FIG. 12 is a partially enlarged plan view showing the semiconductor device A30, and corresponds to FIG. 8. The semiconductor device A30 according to the present embodiment is different from the first embodiment in that the wires 62 are electrically connected to the electrode pads 33a of the semiconductor element 3. The configurations and operations of other parts of the present embodiment are the same as those of the first embodiment. The present embodiment may be combined with any part of the first and second embodiments and the variations.

In the semiconductor element 3 according to the present embodiment, the electrode pads 33 additionally include two electrode pads 33a. Each of the wires 62 is bonded to the metal layer 59 formed on the second portion 512b of the support portion 512 on the x1 side in the x direction, and to an electrode pad 33 of the semiconductor element 3.

According to the present embodiment, the support portion 512 on the x1 side in the x direction is electrically conductive to the electrode pads 33a via the wires 62, whereby the die pad portion 511 is electrically conductive to the electrode pads 33a. In other words, the die pad portion 511 is electrically conductive to the electrode pads 33a via the support portion 512 on the x1 side in the x direction and the wires 62, instead of being directly and electrically connected to the electrode pads 33a via bonding wires. This allows the semiconductor device A30 to make the semiconductor element 3 and the die pad portion 511 electrically conductive to each other even when the die pad portion 511 does not have enough space for bonding a bonding wire. In addition, according to the present embodiment, the support portion 512 on the x1 side in the x direction is electrically conductive to the electrode pads 33a via the wires 62. Thus, even when the semiconductor device A30 does not include the lead 52 (the lead 52a in FIG. 12) electrically conductive to the electrode pads 33a, the semiconductor element 3 and the die pad portion 511 can be electrically conductive to each other. Further, the semiconductor device A30 has advantages common to the semiconductor device A10 owing to its common configuration with the semiconductor device A10.

### Fourth Embodiment

FIG. 13 is a view for explaining a semiconductor device A40 according to a fourth embodiment of the present disclosure. FIG. 13 is a plan view showing the semiconductor device A40, and corresponds to FIG. 2. For convenience of understanding, FIG. 13 shows the sealing resin 7 in phantom, and the outer shape of the sealing resin 7 is indicated by an imaginary line (two-dot chain line). The semiconductor device A40 according to the present embodiment is different from the first embodiment in that the semiconductor device A40 is provided in a quad flat package (QFP). The configurations and operations of other parts of the present embodiment are the same as those of the first embodiment. The present embodiment may be combined with any part of the first to third embodiments and the variations.

The semiconductor device A40 according to the present embodiment is provided in a QFP. The semiconductor device A40 further includes a plurality of leads 52 disposed on the x1 side in the x direction and on the x2 side in the x direction with respect to the lead 51, in addition to the leads 52 disposed on the y1 side in the y direction and the y2 side in the y direction with respect to the lead 51. The terminal portions 522 of the leads 52 disposed on the x1 side in the x direction with respect to the lead 51 protrude from the sealing resin 7 to the x1 side in the x direction, and are arranged at equal intervals in the y direction. The terminal portions 522 of the leads 52 disposed on the x2 side in the x direction with respect to the lead 51 protrude from the sealing resin 7 to the x2 side in the x direction, and are arranged at equal intervals in the y direction. The lead 51 includes four support portions 512. As viewed in the z direction, each of the support portions 512 extends from one of the four corners of the die pad portion 511 to the direction intersecting the x direction and the y direction.

According to the present embodiment, the support portion 512 on the x1 side in the x direction and the y1 side in the y direction is electrically conductive to the electrode pad 33a via the wire 62, the pad portion 521a of the lead 52a, and the wire 61a, whereby the die pad portion 511 is electrically conductive to the electrode pad 33a. In other words, the die pad portion 511 is electrically conductive to the electrode pad 33a via the support portion 512 on the x1 side in the x direction and the y1 side in the y direction, the wire 62, the pad portion 521a, and the wire 61a, instead of being directly and electrically connected to the electrode pad 33a via a bonding wire. This allows the semiconductor device A40 to make the semiconductor element 3 and the die pad portion 511 electrically conductive to each other even when the die pad portion 511 does not have enough space for bonding a bonding wire. Further, the semiconductor device A40 has advantages common to the semiconductor device A10 owing to its common configuration with the semiconductor device A10.

As can be understood from the fourth embodiment, the package type of the semiconductor device according to the present disclosure is not particularly limited. For example, the semiconductor device according to the present disclosure may be provided in a small outline non-leaded package (SON package) or in a quad flat non-leaded package (QFN package) where the terminal portions 522 do not protrude from the sealing resin 7.

Although the first to fourth embodiments have been described with an example where the semiconductor element 3 is an LSI, the present disclosure is not limited to this. The semiconductor element 3 may be a discrete semiconductor element.

The semiconductor device according to the present disclosure is not limited to the above embodiments. Various design changes can be made to the specific configurations of the components in the semiconductor device according to the present disclosure. The present disclosure includes the embodiments described in the following clauses.

### Clause 1.

A semiconductor device (A10) comprising:
a semiconductor element (3);
a first lead (51) including a die pad portion (511) that includes a die-pad obverse surface (511a) facing a first side in a thickness direction (z1 side in a z direction) and having the semiconductor element mounted thereon, and a support portion (512) supporting the die pad portion;
a sealing resin (7) covering the semiconductor element; and
a first connecting member (62) electrically connected to the support portion and electrically conductive to the semiconductor element.

### Clause 2.

The semiconductor device according to clause 1, wherein the support portion includes a connecting surface (512d) to which the first connecting member is electrically connected, and
the connecting surface and the die-pad obverse surface are different in position in the thickness direction.

### Clause 3.

The semiconductor device according to clause 1 or 2, further comprising a second lead (52a) spaced apart from the first lead and including a second terminal portion (522a) exposed from the sealing resin,
wherein the first connecting member is electrically connected to the second lead.

### Clause 4.

The semiconductor device according to clause 3, further comprising a second connecting member (61a) bonded to the semiconductor element and electrically conductive to the first connecting member.

### Clause 5.

The semiconductor device according to clause 4, wherein the second connecting member is electrically connected to the second lead.

### Clause 6. (Second Embodiment, FIG. 11)

The semiconductor device according to clause 4, wherein the second connecting member is electrically connected to the support portion.

### Clause 7. (Second Variation of First Embodiment, FIG. 10)

The semiconductor device according to any of clauses 3 to 6, wherein the first connecting member is a plate-like portion integrally connected to the support portion and the second lead, and
a surface of the first connecting member that faces the first side is flush with a surface of the support portion that faces the first side at a portion to which the first connecting member is connected, and is flush with a surface of the second lead that faces the first side at a portion to which the first connecting member is connected.

### Clause 8.

The semiconductor device according to any of clauses 3 to 6, wherein the first connecting member is a bonding wire.

### Clause 9. (Third Embodiment, FIG. 12)

The semiconductor device according to clause 1 or 2, wherein the first connecting member is a bonding wire, and is bonded to the semiconductor element.

### Clause 10.

The semiconductor device according to clause 8 or 9, further comprising a metal layer (59) formed on the support portion,
wherein the first connecting member is bonded to the metal layer.

### Clause 11.

The semiconductor device according to any of clauses 1 to 10, further comprising a plurality of third leads (52) aligned in a first direction (x direction) perpendicular to the thickness direction,
the sealing resin includes a first resin side surface (73) facing in the first direction, and
the support portion is exposed from the first resin side surface.

### Clause 12. (Fourth Embodiment, FIG. 13)

The semiconductor device according to any of clauses 1 to 10, further comprising:
a plurality of third leads aligned in a first direction perpendicular to the thickness direction, and
a plurality of fourth leads (52) aligned in a second direction (y direction) perpendicular to the thickness direction and the first direction,
wherein as viewed in the thickness direction, the support portion extends in a direction intersecting the first direction and the second direction.

### Clause 13.

The semiconductor device according to any of clauses 1 to 12, wherein the semiconductor element includes an element obverse surface (31) facing the first side, and
a first area (S1) of the element obverse surface is 50% to 90% of a second area (S2) of the die-pad obverse surface.

### Clause 14.

The semiconductor device according to any of clauses 1 to 13, wherein the die pad portion includes a die-pad reverse surface (511b) facing away from the die-pad obverse surface in the thickness direction, and
the die-pad reverse surface is exposed from the sealing resin.

### Clause 15.

The semiconductor device according to any of clauses 1 to 14, wherein the semiconductor element is an LSI.

| | | |
|---|---|---|
| A10, A11, A12, A20, A30, A40: | | |
| Semiconductor device | | |
| 3: Semiconductor element | 31: Element obverse surface | |
| 32: Element reverse surface | 33, 33a: Electrode pad | |
| 4: Bonding member | 5: Conductive support member | |
| 51: Lead | 511: Die pad portion | |
| 511a: Die-pad obverse surface | 511b: Die-pad reverse surface | |
| 512: Support portion | 512a: First portion | |
| 512b: Second portion | 512c: Exposed surface | |
| 512d: Connecting surface | 52, 52a: Lead | |
| 521, 521a: Pad portion | 522, 522a: Terminal portion | |
| 53: Connecting portion | 59: Metal layer | |
| 6, 61, 61a, 62: Wire | 63: Clip | 7: Sealing resin |
| 71: Resin obverse surface | 72: Resin reverse surface | |
| 73, 74: Resin side surface | | |

1. A semiconductor device comprising:
a semiconductor element;
a first lead including a die pad portion that includes a die-pad obverse surface facing a first side in a thickness direction and having the semiconductor element mounted thereon, and a support portion supporting the die pad portion;
a sealing resin covering the semiconductor element; and
a first connecting member electrically connected to the support portion and electrically conductive to the semiconductor element.

2. The semiconductor device according to claim 1, wherein the support portion includes a connecting surface to which the first connecting member is electrically connected, and
the connecting surface and the die-pad obverse surface are different in position in the thickness direction.

3. The semiconductor device according to claim 1, further comprising a second lead spaced apart from the first lead and including a second terminal portion exposed from the sealing resin,
wherein the first connecting member is electrically connected to the second lead.

4. The semiconductor device according to claim 3, further comprising a second connecting member bonded to the semiconductor element and electrically conductive to the first connecting member.

5. The semiconductor device according to claim 4, wherein the second connecting member is electrically connected to the second lead.

6. The semiconductor device according to claim 4, wherein the second connecting member is electrically connected to the support portion.

7. The semiconductor device according to claim 3, wherein the first connecting member is a plate-like portion integrally connected to the support portion and the second lead, and
a surface of the first connecting member that faces the first side is flush with a surface of the support portion that faces the first side at a portion to which the first connecting member is connected, and is flush with a surface of the second lead that faces the first side at a portion to which the first connecting member is connected.

8. The semiconductor device according to claim 3, wherein the first connecting member is a bonding wire.

9. The semiconductor device according to claim 1, wherein the first connecting member is a bonding wire, and is bonded to the semiconductor element.

10. The semiconductor device according to claim 8, further comprising a metal layer formed on the support portion,
wherein the first connecting member is bonded to the metal layer.

11. The semiconductor device according to claim 1, further comprising a plurality of third leads aligned in a first direction perpendicular to the thickness direction,
the sealing resin includes a first resin side surface facing in the first direction, and
the support portion is exposed from the first resin side surface.

12. The semiconductor device according to claim 1, further comprising:
a plurality of third leads aligned in a first direction perpendicular to the thickness direction; and
a plurality of fourth leads aligned in a second direction perpendicular to the thickness direction and the first direction,
wherein as viewed in the thickness direction, the support portion extends in a direction intersecting the first direction and the second direction.

13. The semiconductor device according to claim 1, wherein the semiconductor element includes an element obverse surface facing the first side, and
a first area of the element obverse surface is 50% to 90% of a second area of the die-pad obverse surface.

14. The semiconductor device according to claim 1, wherein the die pad portion includes a die-pad reverse surface facing away from the die-pad obverse surface in the thickness direction, and
the die-pad reverse surface is exposed from the sealing resin.

15. The semiconductor device according to claim 1, wherein the semiconductor element is an LSI.
